(19) United States
(12) Patent Application Publication
(10) Pub. No.: US 2025/0331261 A1
(43) Pub. Date: Oct. 23, 2025

(54) WAFER AND SEMICONDUCTOR DEVICE

(71) Applicants: KABUSHIKI KAISHA TOSHIBA, Tokyo (JP); TOSHIBA ELECTRONIC DEVICES & STORAGE CORPORATION, Tokyo (JP)

(72) Inventors: Seiya TAKEDA, Yokohama (JP); Ryoma KANEKO, Ota (JP); Hajime NAGO, Yokohama (JP); Toshiki HIKOSAKA, Kawasaki (JP)

(73) Assignees: KABUSHIKI KAISHA TOSHIBA, Tokyo (JP); TOSHIBA ELECTRONIC DEVICES & STORAGE CORPORATION, Tokyo (JP)

(21) Appl. No.: 19/019,806

(22) Filed: Jan. 14, 2025

(30) Foreign Application Priority Data
Apr. 18, 2024 (JP) 2024-067681

(51) Int. Cl. H10D 62/60; H10D 30/47; H10D 62/824; H10D 64/27

(52) U.S. Cl. CPC H10D 62/60; H10D 30/475; H10D 62/824; H10D 64/512

(57) ABSTRACT

According to one embodiment, a wafer includes a base, and a first layer including Al_{z1}Ga_{1-z1}N (0<z1≤1). The first layer includes a first region and a second region. The first region is between the base and the second region. A first region oxygen concentration in the first region is lower than a base oxygen concentration in the base. The first region oxygen concentration is lower than a second region oxygen concentration in the second region.

### CROSS-REFERENCE TO RELATED APPLICATIONS

This application is based upon and claims the benefit of priority from Japanese Patent Application No. 2024-067681, filed on Apr. 18, 2024; the entire contents of which are incorporated herein by reference.

### FIELD

Embodiments described herein relate generally to a wafer and a semiconductor device.

### BACKGROUND

For example, stable characteristics are desired in semiconductor devices based on wafers including nitrides.

### BRIEF DESCRIPTION OF THE DRAWINGS

FIG. 1 is a schematic cross-sectional view illustrating a wafer according to a first embodiment;

FIG. 2 is a graph illustrating the concentration of elements in a wafer;

FIG. 3 is a graph illustrating the concentration of elements in a wafer;

FIGS. 4A and 4B are microscopic images of the wafer;

FIG. 5 is a schematic cross-sectional view illustrating a wafer according to the first embodiment;

FIG. 6 is a schematic cross-sectional view illustrating a semiconductor device according to the second embodiment; and

FIG. 7 is a schematic cross-sectional view illustrating a semiconductor device according to the second embodiment.

### DETAILED DESCRIPTION

According to one embodiment, a wafer includes a base, and a first layer including Al_{z1}Ga_{1-z1}N (0<z1≤1). The first layer includes a first region and a second region. The first region is between the base and the second region. A first region oxygen concentration in the first region is lower than a base oxygen concentration in the base. The first region oxygen concentration is lower than a second region oxygen concentration in the second region.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

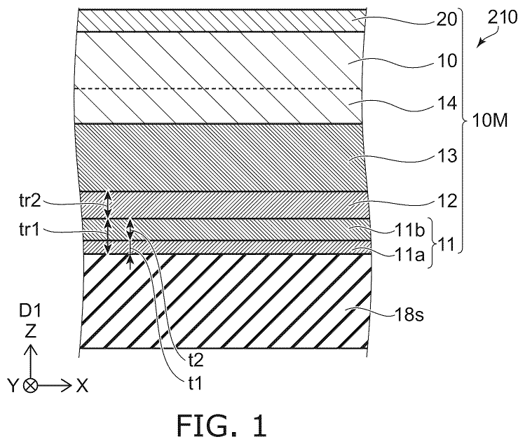

FIG. 1 is a schematic cross-sectional view illustrating a wafer according to a first embodiment.

As shown in FIG. 1, a wafer 210 according to the embodiment includes a base 18s and a first layer 11. The wafer 210 may further include other layers, as described below.

A first direction D1 from the base 18s to the first layer 11 is defined as a Z-axis direction. One direction perpendicular to the Z-axis direction is defined as an X-axis direction. A direction perpendicular to the Z-axis direction and the X-axis direction is defined as a Y-axis direction. The base 18s and the first layer 11 are along the X-Y plane.

The first layer 11 includes Al_{z1}Ga_{1-z1}N (0<z1≤1). The composition ratio z1 may be, for example, not less than 0.8 and not more than 1. The first layer 11 may be, for example, an AlN layer.

The first layer 11 includes a first region 11a and a second region 11b. The first region 11a is provided between the base 18s and the second region 11b. It has been found that the amount of warpage of the base 18s differs depending on the relationship between the oxygen concentrations in these regions.

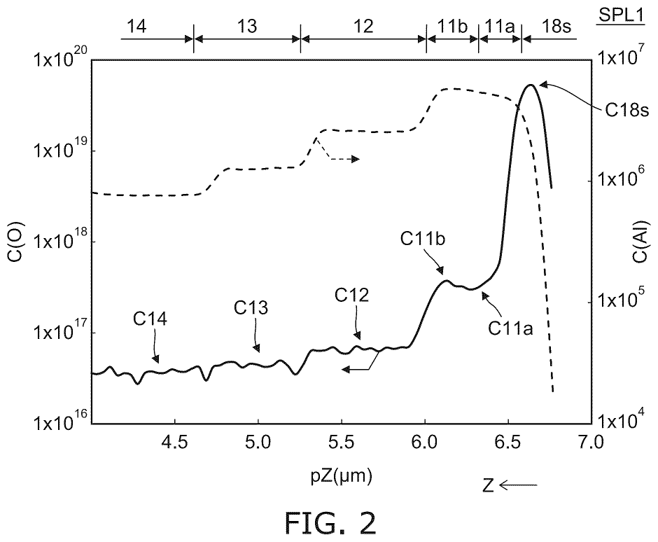

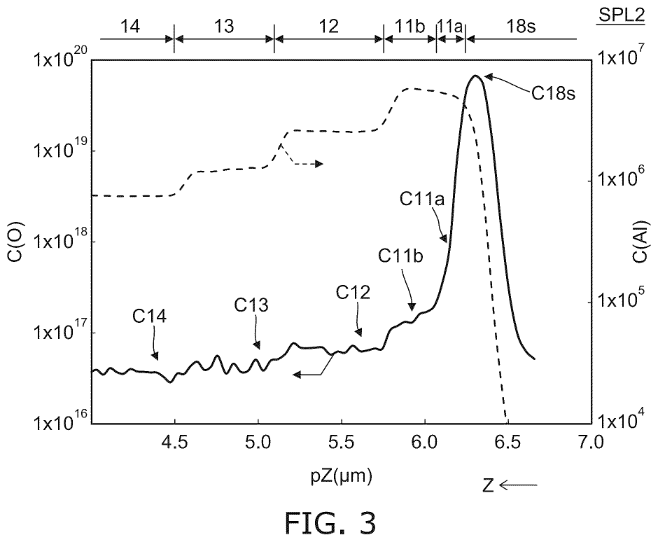

FIGS. 2 and 3 are graphs illustrating the concentration of elements in a wafer.

These horizontal axes are a position pZ in the Z-axis direction (thickness direction). The left axis of these figures is the oxygen concentration C(O). The right axis of these figures is the count number C(Al) of Al. FIG. 2 corresponds to a first sample SPL1. FIG. 3 corresponds to a second sample SPL2.

As shown in FIG. 2, in the first sample SPL1, a first region oxygen concentration C11a in the first region 11a is lower than a base oxygen concentration C18s in the base 18s. The first region oxygen concentration C11a is lower than a second region oxygen concentration C11b in the second region 11b.

As shown in FIG. 3, in the second sample SPL2, the first region oxygen concentration C11a in the first region 11a is lower than the base oxygen concentration C18s in the base 18s. The first region oxygen concentration C11a is higher than the second region oxygen concentration C11b in the second region 11b.

In this way, the first sample SPL1 and the second sample SPL2 have different oxygen profiles. On the other hand, in the first sample SPL1, the amount of warpage of the wafer 210 is 32 μm. In the second sample SPL2, the amount of warpage of the wafer 210 is 96 μm.

By the oxygen concentration profile in the first layer 11, the warpage of the wafer can be suppressed. For example, the occurrence of cracks can be suppressed. Characteristic instability caused by cracks, etc. can be suppressed. According to the embodiment, it is possible to provide a wafer with stable characteristics.

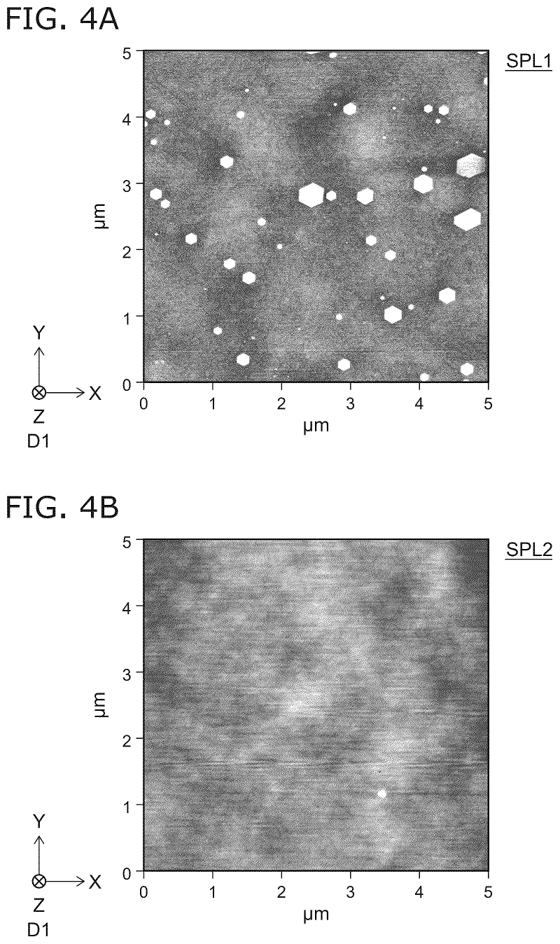

FIGS. 4A and 4B are microscopic images of the wafer.

These figures are AFM (Atomic Force Microscope) images of the surface of the first layer 11 of the wafer 210. FIG. 4A corresponds to the first sample SPL1. FIG. 4B corresponds to the second sample SPL2. As shown in FIG. 4B, the surface of the second sample SPL2 is relatively homogeneous. As shown in FIG. 4A, island-shaped regions (convex portions) are observed in the first sample SPL1. In the first sample SPL1, it is thought that the island-like regions (convex portions) relieve stress and reduce the amount of warpage.

In the embodiment, the base oxygen concentration C18s may be high. For example, the interfacial properties between the first layer 11 and the base 18s are improved. For example, the dislocation density of the first layer 11 can be lowered.

In the embodiment, the second r oxygen concentration C11b may be lower than the base oxygen concentration C18s. By the first region oxygen concentration C11a and the second region oxygen concentration C11b being lower than the base oxygen concentration C18s, occurrence of excessive unevenness is suppressed. By appropriate unevenness, a small amount of warpage can be obtained. For example, high crystal quality can be maintained.

The difference between the first sample SPL1 and the second sample SPL2 can be obtained, for example, by changing the conditions for forming the first layer 11 (for example, epitaxial growth). For example, by setting the oxygen concentration of the atmosphere in the formation of the second region 11b higher than that in the formation of the first region 11a, it becomes easier to obtain the second region oxygen concentration C11b being high. For example, by setting the concentration of water in the atmosphere in the formation of the second region 11b higher than that in the formation of the first region 11a, it becomes easier to obtain the second region oxygen concentration C11b being high. For example, by making the concentration of water in the Al source gas higher in the formation of the second region 11b than in the formation of the first region 11a, it becomes easier to obtain the second region oxygen concentration C11b being high. For example, by making the concentration of water in the nitrogen source gas in forming the second region 11b lower than that in forming the first region 11a, it becomes easier to obtain the second region oxygen concentration C11b being high.

In the embodiment, the first region 11a is in contact with the base 18s. The second region 11b may be in contact with the first region 11a. The base 18s includes silicon, for example.

The first region oxygen concentration C11a may be, for example, not less than 1×10¹⁶ cm⁻³ and not more than 5×10¹⁷ cm⁻³. The second region oxygen concentration C11b may be, for example, not less than 1×10¹⁷ cm⁻³ and not more than 1×10¹⁸ cm⁻³. The base oxygen concentration C18s may be, for example, not less than 1×10¹⁸ cm⁻³ and not more than 1×10²⁰ cm⁻³.

A first layer thickness tr1 (see FIG. 1) of the first layer 11 may be, for example, not less than 100 nm and not more than 200 nm. A first region thickness t1 (see FIG. 1) of the first region 11a may be, for example, not less than 50 nm and not more than 100 nm. A second region thickness t2 (see FIG. 1) of the second region 11b may be, for example, not less than 50 nm and not more than 100 nm.

As shown in FIG. 1, the wafer 210 may further include a second layer 12. The second layer 12 includes Al_{z2}G_{a1-z}2N (0<z2<1, z2<z1). The first layer 11 is provided between the base 18s and the second layer 12. Like the first sample SPL1 in FIG. 2, the second layer 12 does not include oxygen. Alternatively, a second layer oxygen concentration C12 in the second layer 12 is lower than the second region oxygen concentration C11b. The second layer oxygen concentration C12 may be lower than the first region oxygen concentration C11a. The second layer 12 is, for example, an AlGaN layer. The composition ratio of Al in the second layer 12 may decrease as the distance from the second layer 12 increases. A second layer thickness tr2 (see FIG. 1) of the second layer 12 may be, for example, not less than 10 nm and not more than 500 nm.

As shown in FIG. 1, the wafer 210 may further include a third layer 13. The third layer 13 includes Al_{z3}Ga_{1-z3}N (0≤z3≤1). The second layer 12 is provided between the first layer 11 and the third layer 13. Like the first sample SPL1 in FIG. 2, the third layer 13 does not include oxygen. Alternatively, a third layer oxygen concentration C13 in the third layer 13 is lower than the second region oxygen concentration C11b. The third layer oxygen concentration C13 may be lower than the first region oxygen concentration C11a.

As shown in FIG. 1, the wafer 210 may further include a fourth layer 14. The fourth layer 14 includes Al_{z4}Ga_{1-z4}N (0≤z4≤1). The fourth layer 14 may be, for example, a GaN layer. The third layer 13 is provided between the second layer 12 and the fourth layer 14. The fourth layer 14 does not include oxygen. Alternatively, a fourth layer oxygen concentration C14 in the fourth layer 14 is lower than the second region oxygen concentration C11b. The fourth layer oxygen concentration C14 may be lower than the first region oxygen concentration C11a.

As shown in FIG. 1, the wafer 210 may further include a first semiconductor layer 10 and a second semiconductor layer 20. The first semiconductor layer 10 includes Alₓ₁Ga₁₋ₓ₁N (0≤x1<1). The second semiconductor layer 20 includes Alₓ₂Ga₁₋ₓ₂N (0<x2≤1, x1<x2). The first semiconductor layer 10 is provided between the third layer 13 and the second semiconductor layer 20. The first semiconductor layer 10 is provided between the fourth layer 14 and the second semiconductor layer 20. The composition ratio x1 may be, for example, not less than 0 and not more than 0.15. The first semiconductor layer 10 is, for example, a GaN layer. The composition ratio x2 may be, for example, more than 0.15 and not more than 0.3. The second semiconductor layer 20 is, for example, an AlGaN layer.

The concentration of carbon in the fourth layer 14 may be higher than the concentration of carbon in the first semiconductor layer 10.

The first layer 11, the second layer 12, the third layer 13, the fourth layer 14, the first semiconductor layer 10, and the second semiconductor layer 20 are included in the nitride member 10M.

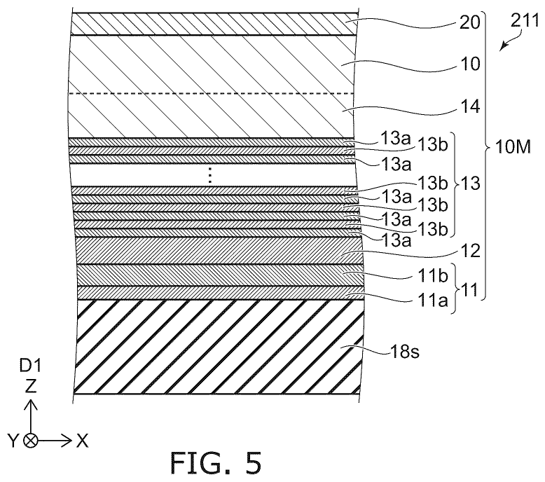

FIG. 5 is a schematic cross-sectional view illustrating a wafer according to the first embodiment.

As shown in FIG. 5, in a wafer 211 according to the embodiment, the third layer 13 includes a plurality of films. The configuration of the wafer 211 except for this may be the same as the configuration of the wafer 210.

In the wafer 211, the third layer 13 includes a plurality of first films 13a and a plurality of second films 13b. In the first direction D1 from the base 18s to the first layer 11, one of the plurality of first films 13a is provided between one of the plurality of second films 13b and another one of the plurality of second films 13b. One of the plurality of second films 13b is provided between one of the plurality of first films 13a and another one of the plurality of first films 13a. The first films 13a include Al_{y1}Ga_{1-y1}N (0<y1≤1). The second films 13b include Al_{y2}Ga_{1-y2}N (0≤y2<y1). The third layer 13 is, for example, a superlattice layer. High crystal quality can be obtained. The amount of warpage can be suppressed.

### Second Embodiment

The second embodiment relates to a semiconductor device. The semiconductor device includes the wafer 210 described in connection with the first embodiment and modifications thereof.

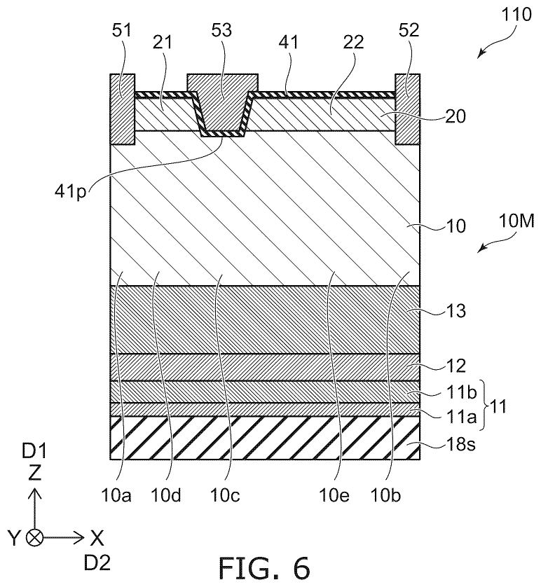

FIG. 6 is a schematic cross-sectional view illustrating a semiconductor device according to the second embodiment.

As shown in FIG. 6, the semiconductor device 110 according to the embodiment includes the wafer 210 according to the first embodiment, a nitride member 10M, a first electrode 51, a second electrode 52, and a third electrode 53.

The nitride member 10M includes, for example, the first semiconductor layer 10 and the second semiconductor layer 20. The first semiconductor layer 10 includes Alₓ₁Ga₁₋ₓ₁N (0≤x1<1). The second semiconductor layer 20 includes Alₓ₂Ga₁₋ₓ₂N (0<x2≤1, x1<x2). The composition ratio x1 may be, for example, not less than 0 and not more than 0.15. The first semiconductor layer 10 is, for example, a GaN layer. The composition ratio x2 may be, for example, more than 0.15 and not more than 0.3. The second semiconductor layer 20 is, for example, an AlGaN layer.

The first semiconductor layer 10 is provided between the third layer 13 and the second semiconductor layer 20. The first semiconductor layer 10 is provided between the fourth layer 14 (see FIG. 1) and the second semiconductor layer 20.

A second direction D2 from the first electrode 51 to the second electrode 52 crosses the first direction D1. The second direction D2 is, for example, the X-axis direction. A position of the third electrode 53 in the second direction D2 is between a position of the first electrode 51 in the second direction D2 and a position of the second electrode 52 in the second direction D2.

The second semiconductor layer 20 includes a first semiconductor portion 21 and a second semiconductor portion 22. A direction from the first semiconductor portion 21 to the second semiconductor portion 22 is along the second direction D2. The first electrode 51 is electrically connected to the first semiconductor portion 21. The second electrode 52 is electrically connected to the second semiconductor portion 22.

Current flowing between the first electrode 51 and the second electrode 52 is controlled by a potential of the third electrode 53. The potential of the third electrode 53 may be, for example, a potential based on a potential of the first electrode 51. The first electrode 51 functions, for example, as a source electrode. The second electrode 52 functions as a drain electrode. The third electrode 53 functions as a gate electrode. The semiconductor device 110 is, for example, a transistor.

The first semiconductor layer 10 includes a region facing the second semiconductor layer 20. A carrier region is formed in this region. The carrier region is, for example, a two-dimensional electron gas. The semiconductor device 110 is, for example, a HEMT (High Electron Mobility Transistor).

In the semiconductor device 110 according to the embodiment, for example, cracks are suppressed. According to the embodiment, a semiconductor device that can obtain stable characteristics can be provided.

As shown in FIG. 6, in this example, at least a part of the third electrode 53 is provided between the first semiconductor portion 21 and the second semiconductor portion 22 in the second direction D2. The third electrode 53 is, for example, a recessed gate electrode. For example, a high threshold voltage can be obtained. For example, normally-off operation is obtained. At least a part of the third electrode 53 may be provided between a part of the first semiconductor layer 10 and another part of the first semiconductor layer 10 in the second direction D2.

For example, the first semiconductor layer 10 includes a first partial region 10a, a second partial region 10b, a third partial region 10c, a fourth partial region 10d, and a fifth partial region 10e. A direction from the first partial region 10a to the first electrode 51 is along the first direction D1. A direction from the second partial region 10b to the second electrode 52 is along the first direction D1. A direction from the third partial region 10c to the third electrode 53 is along the first direction D1.

A position of the fourth partial region 10d in the second direction D2 is between a position of the first partial region 10a in the second direction D2 and a position of the third partial region 10c in the second direction D2. A position of the fifth partial region 10e in the second direction D2 is between the position of the third partial region 10c in the second direction D2 and a position of the second partial region 10b in the second direction D2.

A direction from the fourth partial region 10d to the first semiconductor portion 21 is along the first direction D1. A direction from the fifth partial region 10e to the second semiconductor portion 22 is along the first direction D1. In this example, a part of the third electrode 53 is located between the fourth partial region 10d and the fifth partial region 10e in the second direction D2. A high threshold voltage can be obtained. For example, normally-off operation can be stably obtained.

As shown in FIG. 6, the semiconductor device 110 may further include a first insulating member 41. The first insulating member 41 includes a first insulating portion 41p. The first insulating portion 41p is provided between the third electrode 53 and the nitride member 10M. The first insulating portion 41p functions, for example, as a gate insulating film.

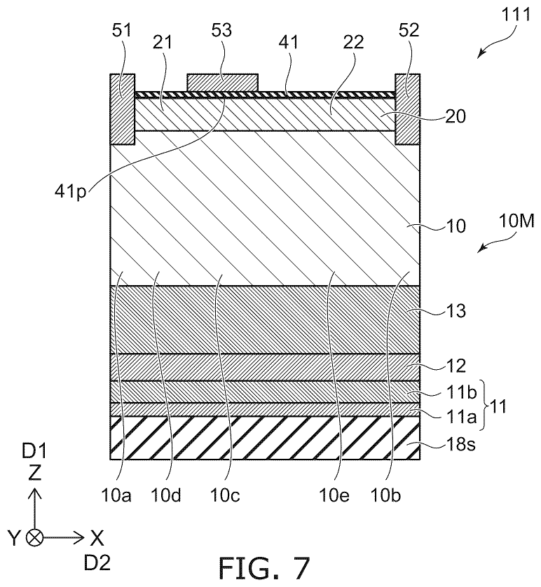

FIG. 7 is a schematic cross-sectional view illustrating a semiconductor device according to the second embodiment.

As shown in FIG. 7, a semiconductor device 111 according to the embodiment includes the wafer 210 according to the first embodiment, the nitride member 10M, the first electrode 51, the second electrode 52, and the third electrode 53. In the semiconductor device 111, the third electrode 53 does not overlap the second semiconductor layer 20 in the second direction D2. The configuration of the semiconductor device 111 except for this may be the same as that of the semiconductor device 110.

In the semiconductor device 111, for example, normally-on operation can be obtained. In the semiconductor device 111, the first insulating member 41 may be omitted. The semiconductor device 111 may be used as a high frequency switching element, for example.

In the embodiment, information regarding the shape of the nitride region, etc. can be obtained, for example, by electron microscopic observation. Information regarding the composition and element concentration in the nitride region can be obtained by, for example, EDX (Energy Dispersive X-ray Spectroscopy) or SIMS (Secondary Ion Mass Spectrometry). Information regarding the composition in the nitride region may be obtained, for example, by reciprocal space mapping.

The embodiments may include the following Technical proposals:

### Technical Proposal 1

A wafer, comprising:
a base; and
a first layer including Al_{z1}Ga_{1-z1}N (0<z1≤1),
the first layer including a first region and a second region,
the first region being between the base and the second region,
a first region oxygen concentration in the first region being lower than a base oxygen concentration in the base, and
the first region oxygen concentration being lower than a second region oxygen concentration in the second region.

### Technical Proposal 2

The wafer according to Technical proposal 1, wherein
the second region oxygen concentration is lower than the base oxygen concentration.

### Technical Proposal 3

The wafer according to Technical proposal 1 or 2, wherein
the first region is in contact with the base, and
the second region is in contact with the first region.

### Technical Proposal 4

The wafer according to Technical proposal 3, wherein
the base includes silicon.

### Technical Proposal 5

The wafer according to any one of Technical proposals 1-4, wherein
the first region oxygen concentration is not less than 1×10¹⁶ cm⁻³ and not more than 5×10¹⁷ cm⁻³.

### Technical Proposal 6

The wafer according to Technical proposal 5, wherein
the second region oxygen concentration is 1×10¹⁷ cm⁻³ and not more than 1×10¹⁸ cm⁻³.

### Technical Proposal 7

The wafer according to any one of Technical proposals 1-6, wherein
the base oxygen concentration is 1×10¹⁸ cm⁻³ and not more than 1×10²⁰ cm⁻³.

### Technical Proposal 8

The wafer according to any one of Technical proposals 1-7, wherein
a first layer thickness of the first layer is not less than 100 nm and not more than 200 nm.

### Technical Proposal 9

The wafer according to Technical proposal 8, wherein
a first region thickness of the first region is not less than 50 nm and not more than 100 nm.

### Technical Proposal 10

The wafer according to Technical proposal 9, wherein
a second region thickness of the second region is not less than 50 nm and not more than 100 nm.

### Technical Proposal 11

The wafer according to any one of Technical proposals 1-10, further comprising:
a second layer including Al_{z2}Ga_{1-z2}N (0<z2<1, z2<z1),
the first layer being provided between the base and the second layer, and
the second layer not including oxygen, or a second layer oxygen concentration in the second layer being lower than the second region oxygen concentration.

### Technical Proposal 12

The wafer according to Technical proposal 11, wherein
the second layer oxygen concentration is lower than the first region oxygen concentration.

### Technical Proposal 13

The wafer according to Technical proposal 11 or 12, further comprising:
a third layer including Al_{z3}Ga_{1-z3}N (0≤z3≤1),
the second layer being between the first layer and the third layer, and
the third layer not including oxygen, or a third layer oxygen concentration in the third layer being lower than the second region oxygen concentration.

### Technical Proposal 14

The wafer according to Technical proposal 13, wherein
the third layer oxygen concentration is lower than the first region oxygen concentration.

### Technical Proposal 15

The wafer according to Technical proposal 13 or 14, wherein
the third layer includes a plurality of first films and a plurality of second films,
in a first direction from the base to the first layer, one of the plurality of first films is between one of the plurality of second films and another one of the plurality of second films, the one of the plurality of second films is between the one of the plurality of first films and another one of the plurality of first films,
the plurality of first films include Al_{y1}Ga_{1-y1}N (0<y1≤1), and
the plurality of second films include Al_{y2}Ga_{1-y2}N (0≤y2<y1).

### Technical Proposal 16

The wafer according to any one of Technical proposals 13-15, further comprising:
a fourth layer including Al_{z4}Ga_{1-z4}N (0≤z4≤1),
the third layer being between the second layer and the fourth layer, and
the fourth layer not including oxygen, or a fourth layer oxygen concentration in the fourth layer being lower than the second region oxygen concentration.

### Technical Proposal 17

The wafer according to any one of Technical proposals 13-16, further comprising:
a first semiconductor layer including Alₓ₁Ga₁₋ₓ₁N (0≤x1<1); and
a second semiconductor layer including Alₓ₂Ga₁₋ₓ₂N (0<x2≤1, x1<x2),
the first semiconductor layer being provided between the third layer and the second semiconductor layer.

### Technical Proposal 18

A semiconductor device, comprising:
the wafer according to any one of Technical proposals 1-12;
a first electrode;
a second electrode;
a third electrode;
a first semiconductor layer including Alₓ₁Ga₁₋ₓ₁N (0≤x1<1); and
a second semiconductor layer including Alₓ₂Ga₁₋ₓ₂N (0<x2≤1, x1<x2),
the first semiconductor layer being provided between the first layer and the second semiconductor layer,
a second direction from the first electrode to the second electrode crossing a first direction from the base to the first layer,
a position of the third electrode in the second direction being between a position of the first electrode in the second direction and a position of the second electrode in the second direction,
the second semiconductor layer including a first semiconductor portion and a second semiconductor portion,
a direction from the first semiconductor portion to the second semiconductor portion being along the second direction,
the first electrode being electrically connected to the first semiconductor portion, and
the second electrode being electrically connected to the second semiconductor portion.

### Technical Proposal 19

The semiconductor device according to Technical proposal 18, wherein
at least a part of the third electrode is provided between the first semiconductor portion and the second semiconductor portion in the second direction.

### Technical Proposal 20

The semiconductor device according to Technical proposal 18, wherein
at least a part of the third electrode is provided between a part of the first semiconductor layer and another part of the first semiconductor layer in the second direction.

According to the embodiment, it is possible to provide a wafer and a semiconductor device that can obtain stable characteristics.

In the present specification, the term “electrically connected state” includes a state in which a plurality of conductors are physically in contact and a current flows between the plurality of conductors. The “state of being electrically connected” includes a state in which another conductor is inserted between the plurality of conductors and a current flows between the plurality of conductors.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in the wafers and the semiconductor devices such as bases, layers, electrodes, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all wafers and all semiconductor devices practicable by an appropriate design modification by one skilled in the art based on the wafers and the semiconductor devices described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A wafer, comprising:
a base; and
a first layer including Al_{z1}Ga_{1-z1}N (0<z1≤1),
the first layer including a first region and a second region,
the first region being between the base and the second region,
a first region oxygen concentration in the first region being lower than a base oxygen concentration in the base, and
the first region oxygen concentration being lower than a second region oxygen concentration in the second region.

2. The wafer according to claim 1, wherein
the second region oxygen concentration is lower than the base oxygen concentration.

3. The wafer according to claim 1, wherein
the first region is in contact with the base, and
the second region is in contact with the first region.

4. The wafer according to claim 3, wherein
the base includes silicon.

5. The wafer according to claim 1, wherein
the first region oxygen concentration is not less than 1×10¹⁶ cm⁻³ and not more than 5×10¹⁷ cm⁻³.

6. The wafer according to claim 5, wherein
the second region oxygen concentration is 1×10¹⁷ cm⁻³ and not more than 1×10¹⁸ cm⁻³.

7. The wafer according to claim 1, wherein
the base oxygen concentration is 1×10¹⁸ cm⁻³ and not more than 1×10²⁰ cm⁻³.

8. The wafer according to claim 1, wherein
a first layer thickness of the first layer is not less than 100 nm and not more than 200 nm.

9. The wafer according to claim 8, wherein
a first region thickness of the first region is not less than 50 nm and not more than 100 nm.

10. The wafer according to claim 9, wherein
a second region thickness of the second region is not less than 50 nm and not more than 100 nm.

11. The wafer according to claim 1, further comprising:
a second layer including Al_{z2}Ga_{1-z2}N (0<z2<1, z2<z1),
the first layer being provided between the base and the second layer, and
the second layer not including oxygen, or a second layer oxygen concentration in the second layer being lower than the second region oxygen concentration.

12. The wafer according to claim 11, wherein
the second layer oxygen concentration is lower than the first region oxygen concentration.

13. The wafer according to claim 11, further comprising:
a third layer including Al_{z3}Ga_{1-z3}N (0≤z3≤1),
the second layer being between the first layer and the third layer, and
the third layer not including oxygen, or a third layer oxygen concentration in the third layer being lower than the second region oxygen concentration.

14. The wafer according to claim 13, wherein
the third layer oxygen concentration is lower than the first region oxygen concentration.

15. The wafer according to claim 13, wherein
the third layer includes a plurality of first films and a plurality of second films,
in a first direction from the base to the first layer, one of the plurality of first films is between one of the plurality of second films and another one of the plurality of second films, the one of the plurality of second films is between the one of the plurality of first films and another one of the plurality of first films,
the plurality of first films include Al_{y1}Ga_{1-y1}N (0<y1≤1), and
the plurality of second films include Al_{y2}Ga_{1-y2}N (0≤y2<y1).

16. The wafer according to claim 13, further comprising:
a fourth layer including Al_{z4}Ga_{1-z4}N (0≤z4≤1),
the third layer being between the second layer and the fourth layer, and
the fourth layer not including oxygen, or a fourth layer oxygen concentration in the fourth layer being lower than the second region oxygen concentration.

17. The wafer according to claim 13, further comprising:
a first semiconductor layer including Alₓ₁Ga₁₋ₓ₁N (0≤x1<1); and
a second semiconductor layer including Alₓ₂Ga₁₋ₓ₂N (0<x2≤1, x1<x2),
the first semiconductor layer being provided between the third layer and the second semiconductor layer.

18. A semiconductor device, comprising:
the wafer according to claim 1;
a first electrode;
a second electrode;
a third electrode;
a first semiconductor layer including Alₓ₁Ga₁₋ₓ₁N (0≤x1<1); and
a second semiconductor layer including Alₓ₂Ga₁₋ₓ₂N (0<x2≤1, x1<x2),
the first semiconductor layer being provided between the first layer and the second semiconductor layer,
a second direction from the first electrode to the second electrode crossing a first direction from the base to the first layer,
a position of the third electrode in the second direction being between a position of the first electrode in the second direction and a position of the second electrode in the second direction,
the second semiconductor layer including a first semiconductor portion and a second semiconductor portion,
a direction from the first semiconductor portion to the second semiconductor portion being along the second direction,
the first electrode being electrically connected to the first semiconductor portion, and
the second electrode being electrically connected to the second semiconductor portion.

19. The semiconductor device according to claim 18, wherein
at least a part of the third electrode is provided between the first semiconductor portion and the second semiconductor portion in the second direction.

20. The semiconductor device according to claim 18, wherein
at least a part of the third electrode is provided between a part of the first semiconductor layer and another part of the first semiconductor layer in the second direction.
